(19) United States
(12) Patent Application Publication
(10) Pub. No.: US 2006/0114653 A1
(43) Pub. Date: Jun. 1, 2006

(54) Electronic device

(76) Inventors: Masaru Seto, Nishitama-gun (JP); Hiroshi Nakamura, Ome-shi (JP)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/287,866

(22) Filed: Nov. 28, 2005

(30) Foreign Application Priority Data
Nov. 30, 2004 (JP) 2004-346560

(51) Int. Cl. H05K 7/20

(52) U.S. Cl. 361/695; 361/683

(57) ABSTRACT

A portable computer includes a first housing, a second housing, and a fan unit. The first housing has a first attaching portion, and contains a heat generating member. The second housing is rotatably connected to the first attaching portion. The fan unit is housed in the first attaching portion, and feeds air into the first housing. The fan unit has a plurality of vanes which extend in a width direction of the first housing and the second housing and which are concentrically disposed, and the fan unit sucks air from a rotation shaft direction of the plurality of vanes, and discharges the air in a direction crossing the rotation shaft.

### CROSS-REFERENCE TO RELATED APPLICATIONS

This application is based upon and claims the benefit of priority from the prior Japanese Patent Application No. 2004-346560, filed Nov. 30, 2004, the entire contents of which are incorporated herein by reference.

### BACKGROUND

1. Field

The present invention relates to an electronic device such as a notebook-size computer, more particularly to an electronic device having a built-in fan unit.

2. Description of the Related Art

For example, an amount of heat generated by a heat generating member such as a CPU for use in a portable computer as an electronic device increases with increases of processing speed and functions of the CPU itself. It is supposed that the CPU degrades its efficient operation and falls in an inoperative state, when temperature excessively rises.

Therefore, heretofore, the portable computer is provided with a fan unit as a countermeasure against heat radiation. The fan unit feeds air to a heat generating member such as the CPU. Heat of the heat generating member such as the CPU is taken by the air fed by the fan unit. Accordingly, a heat generating member such as the CPU radiates heat and is cooled. A centrifugal fan has heretofore been adopted in the fan unit. An appearance of the centrifugal fan has a substantially flat rectangular parallelepiped shape in many cases.

This type of electronic device such as a portable computer is provided with a computer main body and a display unit. The computer main body includes a first housing. The display unit includes a second housing. The computer main body is rotatably connected to the display unit.

Accordingly, the display unit is supported by the computer main body in such a manner as to be rotatable between a closed position and an open position.

The closed position refers to a position where the unit lies on the computer main body. The open position refers to a position where the unit rises with respect to the computer main body. The display unit and the computer main body are brought into a folded state in a state in which the display unit is brought into the closed position.

In this type of connection structure, the display unit is supported on a base portion of the computer main body, for example, via a hinge shaft. Since the display unit lies on the computer main body, the base portion of the computer main body can be set to be thicker than the computer main body. Therefore, a comparatively large fan unit is sometimes contained in the base portion of the computer main body. Such a portable computer is disclosed in, for example, Jpn. Utility Model Appln. KOKAI Publication No. 5-25522.

On the other hand, it is demanded that the portable computer be made thinner. With the thinning of the portable computer, the base portion of the computer main body is also miniaturized.

However, when the fan unit is housed in the base portion of the computer main body as disclosed in Jpn. Utility Model Appln. KOKAI Publication No. 5-25522, a size and a shape of the base portion of the computer main body are influenced by those of the fan unit.

Especially, when the fan unit has a substantially flat rectangular parallelepiped appearance, it is supposedly difficult to thin and miniaturize the base portion of the computer main body. Therefore, it is also supposed to be difficult to thin the portable computer. It is further supposed that it is more difficult to thin the portable computer, when the fan unit maintains such a size as to function sufficiently.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a perspective view of a portable computer viewed from its front according to a first embodiment of the present invention;

FIG. 2 is a sectional view taken along a line F2-F2 shown in FIG. 1;

FIG. 3 is an exploded perspective view of a fan unit shown in FIG. 1;

FIG. 4 is an enlarged perspective view of a region surrounded with F4 in FIG. 1;

FIG. 5 is a perspective view of the portable computer shown in FIG. 1, viewed from its rear;

FIG. 6 is a sectional view taken along a line F6-F6 shown in FIG. 1;

FIG. 7 is a sectional view taken along a line F7-F7 shown in FIG. 6;

FIG. 8 is a sectional view of the vicinity of the fan unit of the portable computer viewed from above according to a second embodiment of the present invention;

FIG. 9 is a sectional view taken along a line F9-F9 shown in FIG. 8;

FIG. 10 is a perspective view of a portable computer viewed from its rear according to a third embodiment of the present invention;

FIG. 11 is a sectional view of the vicinity of the fan unit of the portable computer shown in FIG. 10 and viewed from above;

FIG. 12 is a perspective view of a portable computer viewed from its rear according to a fourth embodiment of the present invention;

FIG. 13 is a sectional view of the vicinity of the fan unit along a vertical direction in a state in which the portable computer shown in FIG. 12 is laid on a base; and

FIG. 14 is a perspective view of a portable computer viewed from its front according to a fifth embodiment of the present invention.

### DETAILED DESCRIPTION

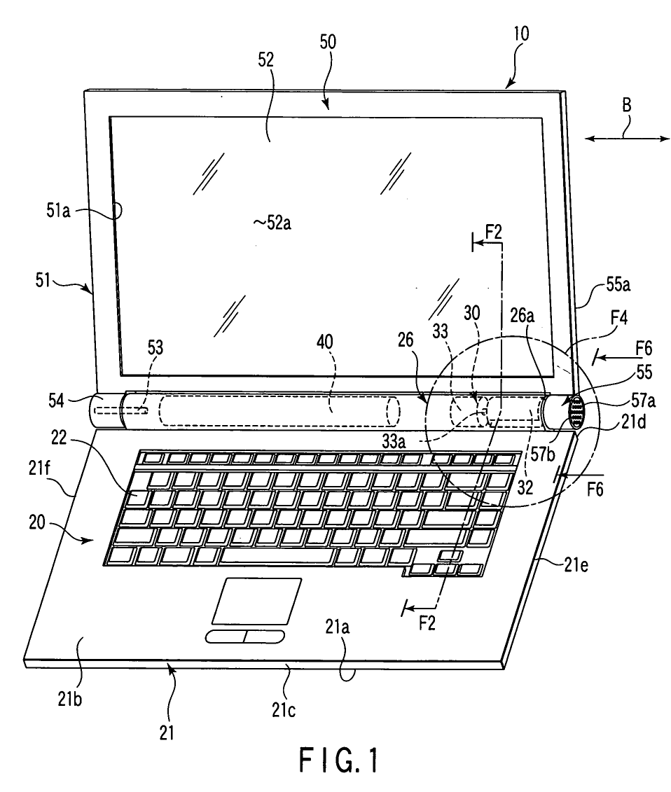

A first embodiment of the present invention will be described with reference to FIGS. 1 to 7.

FIG. 1 shows a portable computer 10 as an electronic device. As shown in FIG. 1, the portable computer 10 includes a computer main body 20 and a display unit 50.

The computer main body 20 includes a first housing 21. The first housing 21 has a substantially flat box shape. The first housing 21 has a bottom wall 21a, an upper wall 21b, a front wall 21c, a rear wall 21d, a left wall 21e, and a right wall 21f.

The upper wall 21b supports a keyboard 22. The front wall 21c, the left wall 21e, the right wall 21f, and the rear wall 21d constitute a peripheral wall along a peripheral direction of the first housing 21.

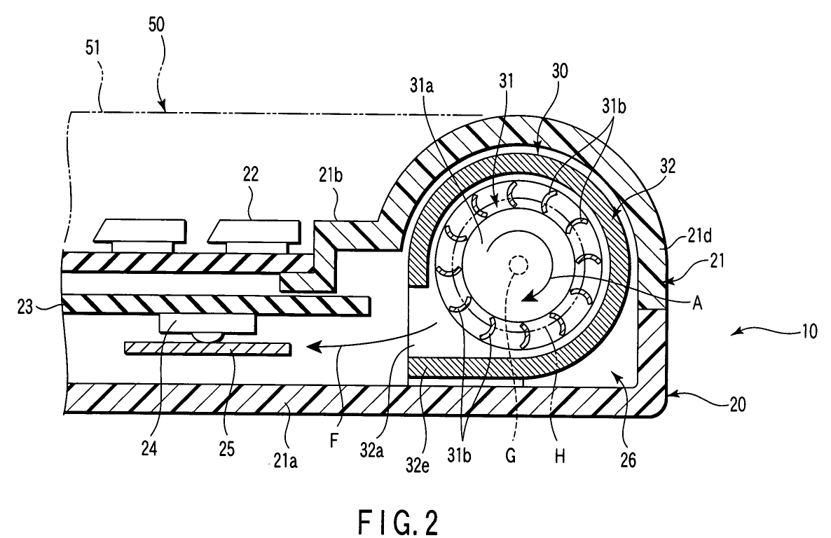

FIG. 2 is a sectional view taken along a line F2-F2 shown in FIG. 1. As shown in FIG. 2, a printed board 23 is housed in the first housing 21. The printed board 23 is disposed substantially parallel to, for example, the bottom wall 21a of the first housing 21.

A heat generating member such as a CPU 24 is attached to a lower surface of the printed board 23. A heat radiating plate 25 is attached to the CPU 24. The heat radiating plate 25 is thermally connected to the CPU 24.

As shown in FIG. 1, a fan housing section 26 as a first attaching portion is formed substantially in a rear central portion of the first housing 21. The fan housing section 26 is formed integrally with the first housing 21. As shown in FIG. 2, the substantially rear central portion of the upper wall 21b of the first housing 21 is raised upwards in a substantially circular shape.

Accordingly, a space defined by the substantially rear central portion of the upper wall 21b and the bottom wall 21a constitutes the fan housing section 26. A height of the fan housing section 26 is larger than that of a portion other than the fan housing section 26 in the space defined between the upper wall 21b and the bottom wall 21a.

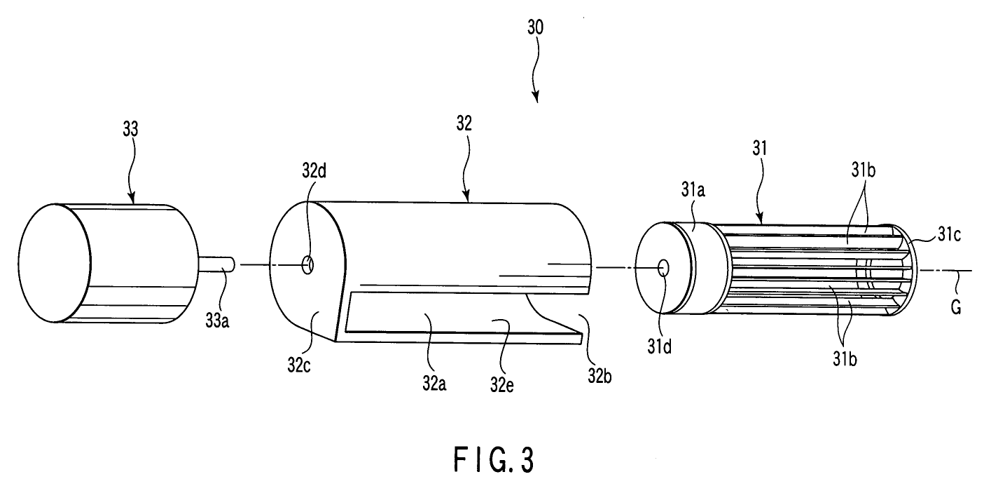

As shown in FIG. 1, a fan unit 30 and a battery 40 are housed in the fan housing section 26. As shown in FIG. 3, the fan unit 30 includes a vane wheel 31, a housing 32, and a driving portion 33.

The vane wheel 31 includes a base portion 31a, and a plurality of vanes 31b. The base portion 31a has a substantially cylindrical shape. The respective vanes 31b are disposed on the base portion 31a. To be more specific, as shown in FIG. 2, one end of each vane 31b is fixed to the same circumference (virtual circle H shown by a two-dot chain line in the drawing) as that of one end surface of the base portion 31a. Moreover, as shown in FIG. 3, each vane 31b extends in an axial direction of the base portion 31a.

An end of each vane 31b on a side opposite to the base portion 31a is supported by a support member 31c. The support member 31c has, for example, a substantial O-shape, and supports one end of each vane 31b. According to the above-described structure, the vane wheel 31 has a substantially cylindrical appearance.

The housing 32 has a substantially cylindrical shape whose one end is closed. The vane wheel 31 is housed in the housing 32. A discharge port 32a is formed in a part of a side wall of the housing 32. The discharge port 32a connects the inside of the housing 32 to the outside thereof. The discharge port 32a extends from an opened end 32b of the housing 32 toward a closed end 32c. The discharge port 32a has, for example, a rectangular shape.

The driving portion 33 is provided with a rotation shaft 33a. The rotation shaft 33a is rotated by the driving portion 33.

A communication hole 32d through which the rotation shaft 33a of the driving portion 33 passes is formed in the closed end 32c of the housing 32. A fitting portion 31d is formed coaxially with the base portion 31a in an end surface of the base portion 31a of the vane wheel 31 on a side opposite to an end surface to which each vane 31b is fixed. The rotation shaft 33a of the driving portion 33 fits into the fitting portion 31d.

The vane wheel 31 is housed in the housing 32 from the side of the base portion 31a. The rotation shaft 33a of the driving portion 33 passes through the communication hole 32d of the housing 32. Accordingly, the rotation shaft 33a passes through the communication hole 32d to fit into the fitting portion 31d of the vane wheel 31. Therefore, when the driving portion 33 is driven, the vane wheel 31 rotates. A rotation shaft G of the vane wheel 31 has the same direction as that of the rotation shaft 33a.

As shown in FIG. 2, when the vane wheel 31 rotates, for example, surrounding air is sucked into the housing 32 from the opened end 32b. The sucked air is pushed outwards by each vane 31b in a peripheral direction of the vane wheel 31. In this case, the air pushed outwards in the peripheral direction of the vane wheel 31 is discharged from the discharge port 32a. It is to be noted that a direction from the discharge port 32a toward the inside of the first housing 21, that is, a direction in which cooling air F travels is a direction crossing the rotation shaft of the vane wheel 31.

Therefore, the shapes of each vane 31b and the housing 32 are devised. Devised respects will be described. As shown in FIG. 2, the sectional shape of each vane 31b is indented with respect to a rotation direction of the vane wheel 31 shown by an arrow A in the drawing. Therefore, each vane 31b effectively pushes out the air in the peripheral direction by gathering the sucked air in this indentation.

In the housing 32, a portion connected to the discharge port 32a in the rotation direction of the vane wheel 31 is a straight-line guide portion 32e. The air pushed out in a circumferential direction is guided into the discharge port 32a by the guide portion 32e. The air guided into the discharge port 32a is discharged as the cooling air F.

In the fan unit 30 constituted as described above, each vane 31b is extended in the axial direction of the rotation shaft G of the vane wheel 31 to thereby increase a discharge amount of the cooling air F. That is, a sucked amount of the air increases. Therefore, even when the vane wheel 31 is miniaturized in a diametric direction, the vane wheel 31 is extended in the direction of the rotation shaft G, that is, each vane 31b is extended in the axial direction of the rotation shaft G, and accordingly a function of the fan unit 30 is sufficiently maintained.

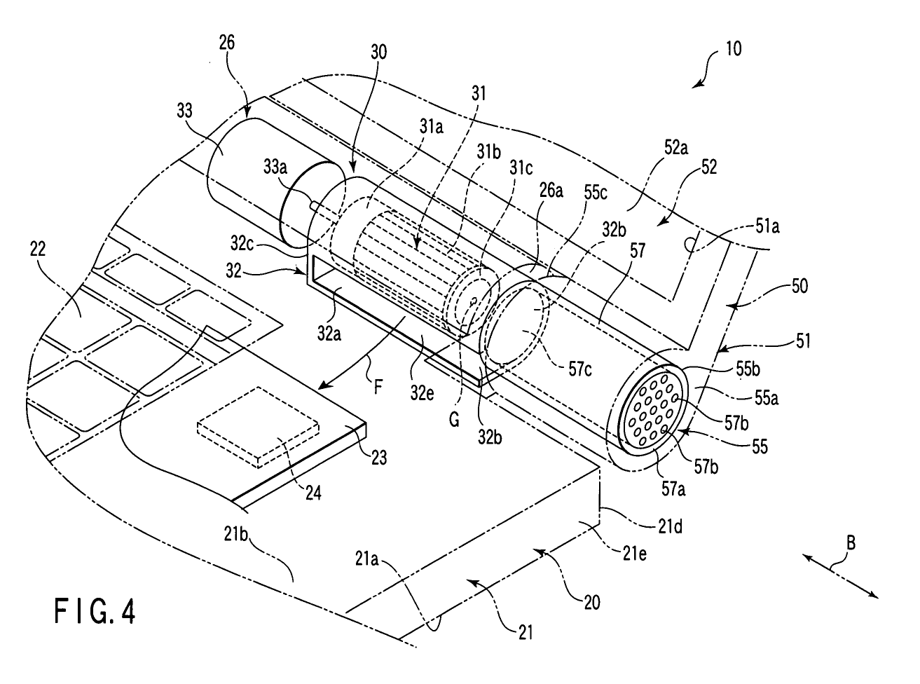

FIG. 4 shows a region surrounded with F4 shown by a one-dot chain line in FIG. 1 in an enlarged size. As shown in FIG. 4, the fan unit 30 constituted as described above is housed in, for example, a left end portion of the fan housing section 26 in a width direction. It is to be noted that a width direction B is a direction from the left wall 21e toward the right wall 21f of the first housing 21 or a direction from the right wall 21f toward the left wall 21e.

An arrangement of the fan unit 30 will be specifically described. The fan unit 30 is disposed in the left end portion of the fan housing section 26. As to a posture of the fan unit 30, the opened end 32b of the housing 32 faces a left end wall 26a of the fan housing section 26, and the discharge port 32a faces the inside of the first housing 21. In this case, the rotation shaft G of the vane wheel 31 extends along, for example, the width direction B.

Accordingly, the cooling air F discharged from the discharge port 32a is fed into the first housing 21. Therefore, the cooling air F is sent to a heat generating member such as the CPU 24, or the heat radiating plate 25. For example, a heat generating member such as the CPU 24 is preferably disposed in a position wherein the cooling air F is effectively fed. As shown in FIG. 2, the discharge port 32a is preferably disposed as high as CPU 24.

The driving portion 33 is connected to, for example, a power supply portion (not shown). The driving portion 33 drives the fan unit 30, for example, at a time when power supply is turned on in the portable computer 10, or a temperature of a heat generating member such as the CPU 24 reaches a predetermined value.

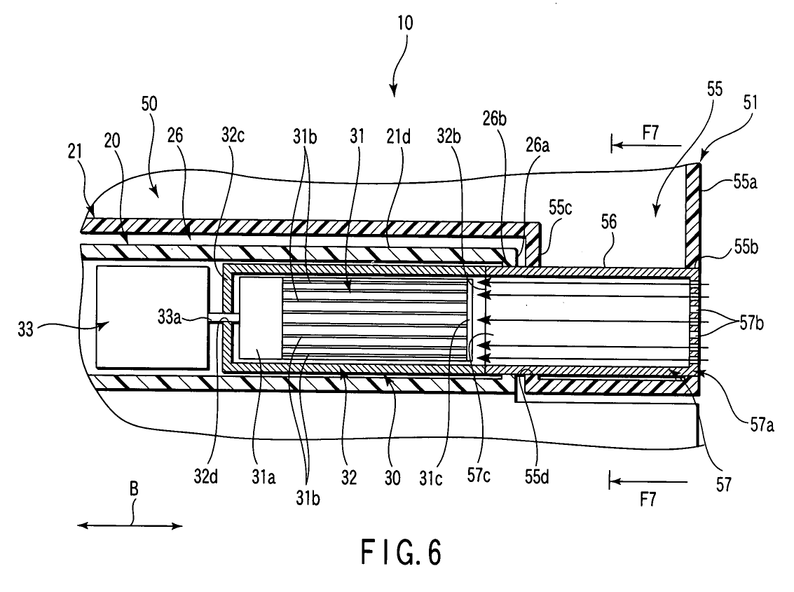

FIG. 6 is a sectional view taken along a line F6-F6 shown in FIG. 1. As shown in FIG. 6, a first through hole 26b is formed along the same axis as that of the housing 32 of the fan unit 30 in the left end wall 26a of the fan housing section 26. The first through hole 26b has a size which is substantially equal to that of, for example, the opened end 32b of the housing 32. The first through hole 26b communicates with the inside and the outside of the fan housing section 26. The air around the portable computer 10 is sucked into the fan unit 30 through the first through hole 26b.

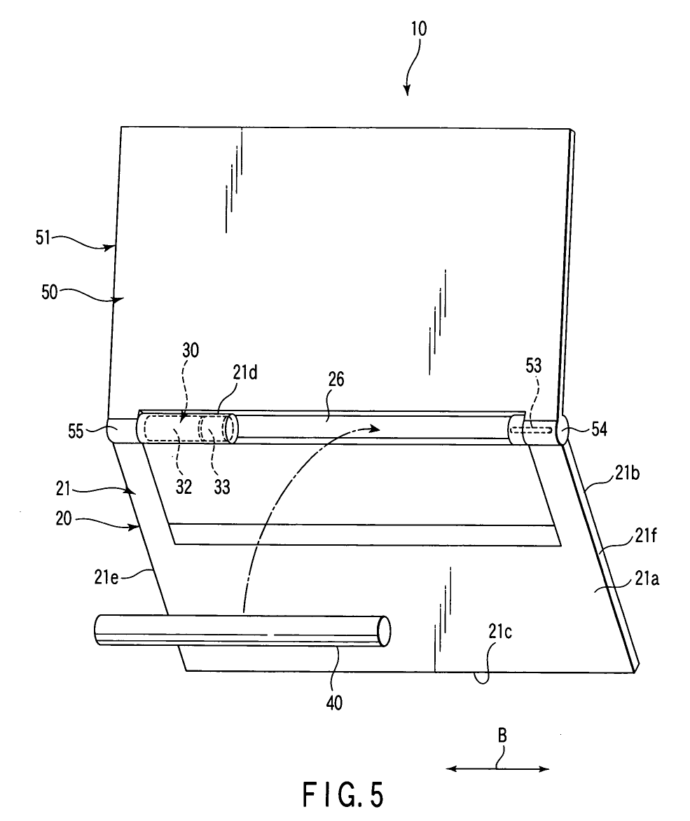

FIG. 5 is a perspective view of the portable computer 10 viewed from a rear side. As shown in FIG. 5, the battery 40 has a substantially cylindrical shape extending in the width direction B. The battery 40 is housed in a space ranging from a right end portion of the fan housing section 26 to a portion in which the fan unit 30 is housed. The battery 40 is detachably attached to, for example, the rear side of the portable computer 10.

As shown in FIG. 1, the display unit 50 includes a second housing 51 and a liquid crystal display panel 52. The liquid crystal display panel 52 is housed in the second housing 51. The liquid crystal display panel 52 has a screen 52a which displays an image. The screen 52a is exposed outwardly from the second housing 51 through an opening 51a formed in a front surface of the second housing 51.

The second housing 51 is connected to the fan housing section 26 of the first housing 21 via a shaft 53 in such a manner as to be rotatable between the closed position and the opened position.

The closed position is a position where the second housing lies on the computer main body 20. The opened position is a position where the second housing 51 rises with respect to the computer main body 20 in such a manner that the keyboard 22 or the screen 52a is exposed. A width direction of the second housing 51 corresponds to the width direction B of the first housing 21.

A connection structure between the first housing 21 and the second housing 51 will be specifically described. The second housing 51 is provided with a connecting portion 54. The connecting portion 54 is formed on a portion of the second housing 51 which faces the right end portion of the fan housing section 26 in the width direction B. That is, the connecting portion 54 overlaps with the fan housing section 26 in the width direction B.

As shown by a dot line, the shaft 53 passes through the connecting portion 54 and the fan housing section 26 along the same axis as that of the first through hole 26b in the width direction B. Therefore, the second housing 51 is rotatable around the shaft 53 with respect to the first housing 21.

It is to be noted that a section of the connecting portion 54 crossing the width direction B has a substantially circular shape. Therefore, even when the second housing 51 rotates with respect to the first housing 21, the housing smoothly rotates. FIG. 2 shows a state in which the second housing 51 is brought into the closed position by a two-dot chain line.

As shown by the two-dot chain line in FIG. 2, since the height of the fan housing section 26 does not exceed that of the second housing 51 disposed in the closed position, the fan housing section 26 does not protrude while the second housing 51 is disposed in the closed position.

Moreover, as shown in FIG. 1, the second housing 51 is provided with a facing portion 55 as a second attaching portion. The facing portion 55 is disposed on a side opposite to the connecting portion 54 via the fan housing section 26 in the second housing 51. Therefore, the facing portion 55 faces the left end portion of the fan housing section 26 in the width direction B.

As shown in FIG. 6, a left end wall 55a of the facing portion 55 is provided with a second through hole 55b along the same axis as that of the first through hole 26b formed in the left end wall 26a of the fan housing section 26. A right end wall 55c of the facing portion 55 is provided with a third through hole 55d along the same axis as that of the first through hole 26b.

The second through hole 55b is formed into a circular shape having a size which is substantially equal to that of the third through hole 55d. The facing portion 55 is bored through the first through hole 26b and the second through hole 55b in the width direction B. The first through hole 26b is slightly larger than, for example, the second through hole 55b and the third through hole 55d.

When the fan unit 30 is driven, the air is sucked through the second through hole 55b. In this case, a portion of the facing portion 55 extending from the second through hole 55b to the third through hole 55d constitutes a guide portion 56 which guide the air into the fan housing section 26.

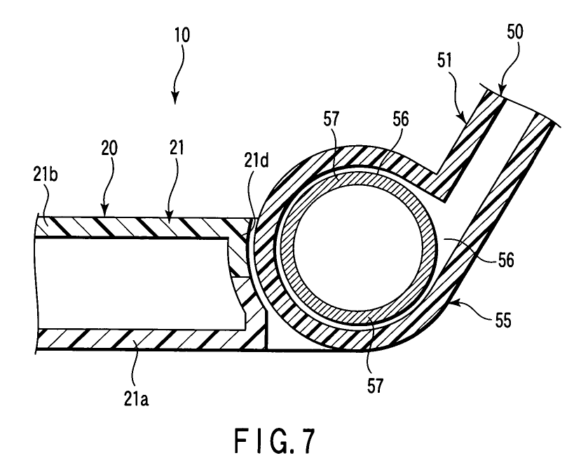

FIG. 7 is a sectional view taken along a line F7-F7 shown in FIG. 6. As shown in FIGS. 6 and 7, a guide member 57 is housed inside the guide portion 56. The guide member 57 has a cylindrical shape extending in the width direction B. The guide member 57 has such a size as to fit in the second through hole 55b and the third through hole 55d. The guide member 57 fits in the second through hole 55b and the third through hole 55d, and is accordingly fixed to the facing portion 55.

The guide member 57 has, for example, a bottom portion. This bottom portion 57a fits in the second through hole 55b in such a manner as to be disposed in the same plane as that of, for example, an edge of the second through hole 55b. The bottom portion 57a is provided with a plurality of suction ports 57b. The plurality of suction ports 57b communicate with the inside and the outside of the guide member 57. The bottom portion 57a may have one suction port 57b only, not a plurality of the suction ports 57b as described above.

The other end of the guide member 57 is opened. This opened end 57c extends through the second through hole 55b and the first through hole 26b to abut on the opened end 32b of the housing 32 of the fan unit 30. Accordingly, the air flows through the guide member 57, and is guided to the fan unit 30.

It is to be noted that the first through hole 26b is slightly larger than the second and third through holes 55b and 55d. Moreover, the guide member 57 is disposed along the same axis as that of the shaft 53. Therefore, the guide member 57 also functions as a shaft which supports the rotation of the second housing 51.

Next, an operation of the fan unit 30 will be described.

When the power supply of the portable computer 10 is turned on, or when the temperature of the CPU 24 or the like reaches the predetermined value, the driving portion 33 drives the fan unit 30. The driving portion 33 rotates the vane wheel 31 connected to the rotation shaft 33a.

As shown in FIG. 6, when the vane wheel 31 rotates, the surrounding air is sucked into the guide member 57 from the suction ports 57b formed in the bottom portion 57a of the guide member 57. The air sucked into the guide member 57 flows through the guide member 57 toward the opened end 57c. Moreover, the air is sucked into the fan unit 30 from the opened end 32b of the housing 32.

As shown in FIG. 2, the air sucked into the fan unit 30 is pushed out in the peripheral direction by each rotating vane 31b. The pushed-out air is discharged as the cooling air F from the discharge port 32a of the housing 32 into the first housing 21.

The discharged cooling air F is guided into a heat generating member such as the CPU 24, or the heat radiating plate 25. The cooling air F which has reached a heat generating member such as the CPU 24, or the heat radiating plate 25 absorbs the heat of the air. Accordingly, a heat generating member such as the CPU 24 is cooled.

In the electronic device constituted in this manner, the fan unit 30 is housed in the fan housing section 26. The fan housing section 26 is higher than another portion of the first housing 21. Moreover, since the fan housing section 26 is formed substantially in the rear central portion of the first housing 21, the fan housing section is formed to be long in the width direction B.

Furthermore, the vane wheel 31 of the fan unit 30 is provided with a plurality of vanes 31b which are concentrically disposed and which extend in the width direction B. Therefore, although the vane wheel 31 is miniaturized in the diametric direction, the wheel extends in the direction of the rotation shaft G (in parallel with the width direction B), and a sufficient function can be maintained.

As described above, even when the fan unit 30 is miniaturized, that is, the vane wheel 31 is miniaturized in the diametric direction with the thinning of the portable computer 10, the function of the fan unit 30 is sufficiently maintained. Furthermore, since the fan unit 30 is housed in the fan housing section 26, the first housing 21 is thinned more. That is, the portable computer 10 is effectively thinned.

Moreover, since the fan housing section 26 is disposed in the first housing 21, the cooling air F discharged from the fan unit 30 is directly discharged into the first housing 21. Therefore, since the cooling air F is easily fed into a heat generating member such as the CPU 24, a heat generating member such as the CPU 24 is effectively cooled.

Moreover, since the suction ports 57b are disposed in the left end wall 55a of the facing portion 55, an air suction passage from the suction ports 57b to the fan unit 30 can be formed into a substantially straight-line shape. Therefore, the fan unit 30 comparatively easily sucks the air. Moreover, since the guide portion 56 is formed in the facing portion 55, the fan unit 30 can effectively suck the air.

Moreover, the facing portion 55 is formed outwardly in the width direction in the second housing 51. That is, anything does not obstruct inflow of the sucked air into the facing portion 55. Therefore, the fan unit 30 can effectively suck the air.

Moreover, since the guide member 57 is disposed in the facing portion 55, the sucked air is more effectively guided into the fan unit 30. The guide member 57 also functions as the shaft which supports the rotation of the second housing 51. Therefore, since the guide member 57 is utilized as the shaft that supports the rotation, the structure of the portable computer 10 can be simplified.

Moreover, the vane wheel 31 is provided with a plurality of vanes 31b extending in the width direction B. Therefore, when a length of each vane 31b is adjusted, the function of the fan unit 30 is comparatively easily adjusted.

Furthermore, since the battery 40 is housed in the fan housing section 26, the portion other than the fan housing section 26 in the first housing 21 can be formed to be thinner than the battery 40. Therefore, the portable computer 10 can be effectively thinned.

Moreover, the suction ports 57b are disposed in the guide member 57. The guide member 57 is supported by the second through hole 55b and the third through hole 55d. In this case, the facing portion 55 is not provided with any special support portion other than the second through hole 55b and the third through hole 55d for supporting the guide member 57. In addition, the guide member 57 is provided with the suction ports 57b. Therefore, when the guide member 57 is supported, the suction ports 57b are directed outwards.

That is, since the facing portion 55 is provided with the second and third through holes 55b and 55d to support the guide member 57, and the support portion of the guide member 57 and the suction ports 57b are disposed dividedly in the facing portion 55 and the guide member 57, the structure of the facing portion 55 is simplified.

It is to be noted that the present embodiment has a structure in which the guide member 57 has the bottom portion 57a, and the suction ports 57b are formed in the bottom portion 57a. However, the present invention is not limited to the present embodiment. The guide member 57 may be formed into a cylindrical shape whose opposite ends are opened. In this case, the left end wall 55a of the facing portion 55 may be provided with the suction ports 57b facing the guide member 57 without disposing the second through hole 55b.

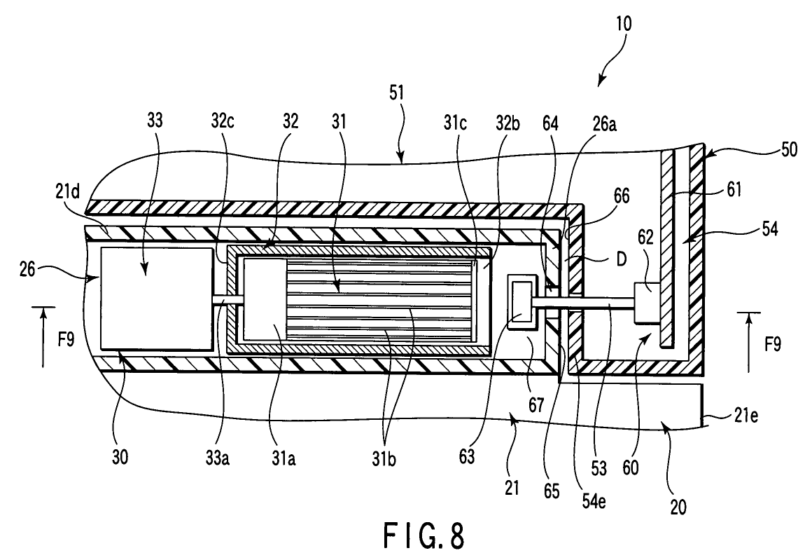

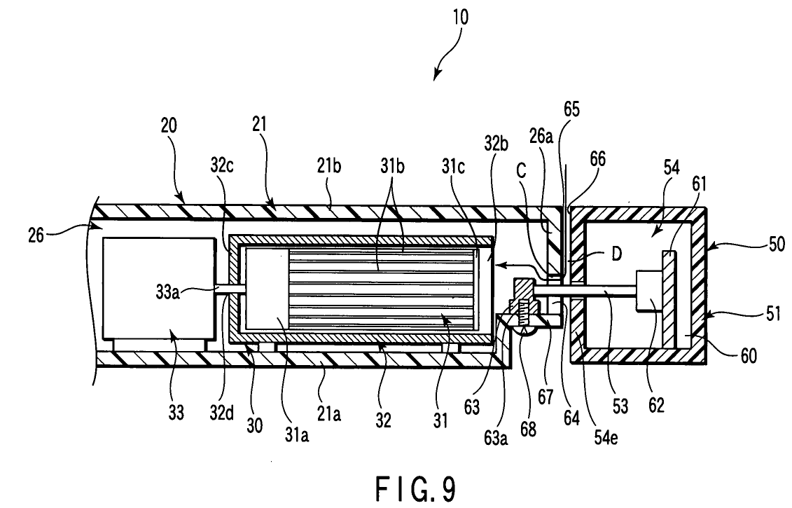

Next, a portable computer 10 will be described according to a second embodiment of the present invention with reference to FIGS. 8 and 9.

The second embodiment is different from the first embodiment in that a connecting portion 54 is disposed in a portion of a second housing 51 in which a facing portion 55 has been disposed. That is, in the second embodiment, a fan housing section 26 is sandwiched between a pair of connecting portions 54 in a width direction B. It is to be noted that a constitution having a function similar to that of the first embodiment is denoted with the same reference numerals, and description thereof is omitted.

FIG. 8 is a sectional view showing, in an enlarged size, a state in which the vicinity of a fan unit 30 is viewed from above in the second embodiment. FIG. 9 is a sectional view taken along a line F9-F9 shown in FIG. 8.

As shown in FIGS. 8 and 9, the connecting portions 54 are rotatably connected to the fan housing section 26 via a shaft 53 passed in the width direction B. A connecting structure of the connecting portions 54 to the fan housing section 26 will be described typically in accordance with a connecting structure of the connecting portion 54 disposed in a left end portion of the second housing 51 with respect to the fan housing section 26.

The connecting portion 54 is provided with a support portion 60 which rotatably supports one end of the shaft 53. The support portion 60 includes, for example, a base portion 61 and a bearing portion 62. The base portion 61 is fixed to the second housing 51, and extends along a peripheral wall of, for example, the second housing 51.

The bearing portion 62 is fixed to the surface of the base portion 61 facing the fan housing section 26. The bearing portion 62 rotatably supports one end of the shaft 53. A communication hole which passes the shaft 53 is formed in a right end wall 54e (wall facing the fan housing section 26) of the connecting portion 54 disposed in the left end portion of the second housing 51.

The other end of the shaft 53 is provided with a fixed portion 63. The fixed portion 63 does not rotate with respect to the shaft 53. An opening 64 which passes the shaft 53 is formed in a left end wall 26a of the fan housing section 26. The opening 64 communicates with the inside and the outside of the fan housing section 26.

As shown in FIG. 9, a gap C is formed between an inner surface of the opening 64 and an outer surface of the shaft 53. A gap D is formed between the fan housing section 26 and the connecting portion 54 (between a left end surface 65 of the fan housing section 26 and a right end surface 66 of the connecting portion 54). Accordingly, surrounding air flows through these gaps C and D into the fan housing section 26. Each of the gaps C and D has a size of, for example, about 1 to 2 mm.

In a bottom wall 21a of a first housing 21, the vicinity of the left end wall 26a is formed substantially into such an L-shape that a sectional shape is bent upwards, and there is formed a fixed seat 67 in which the fixed portion 63 of the shaft 53 is disposed.

The fixed portion 63 is provided with a screw hole 63a. A female screw is formed in the screw hole 63a. When the fixed portion 63 is disposed on the fixed seat 67, a screw 68 passes through the fixed seat 67 to engage with the screw hole 63a, and accordingly the fixed portion 63 is fastened to the fixed seat 67.

According to the above-described connection structure, a first housing 21 is rotatably connected to the second housing 51. In the second embodiment, the connecting portion 54 disposed in the left end portion of the second housing 51 is a second attaching portion mentioned in the present invention.

In the portable computer 10 constituted in this manner, the fan unit 30 is disposed in a portion of the fan housing section 26 facing the connecting portion 54. However, since the gaps C and D are disposed, the fan unit 30 can sufficiently suck the air. Therefore, an effect similar to that of the first embodiment can be obtained in the second embodiment.

It is to be noted that in the present embodiment, there have been described the connecting portion 54 disposed on the left end portion of the second housing 51. The support portion 60 of the connecting portion 54 disposed in a right end portion of the second housing 51 is substantially similarly disposed.

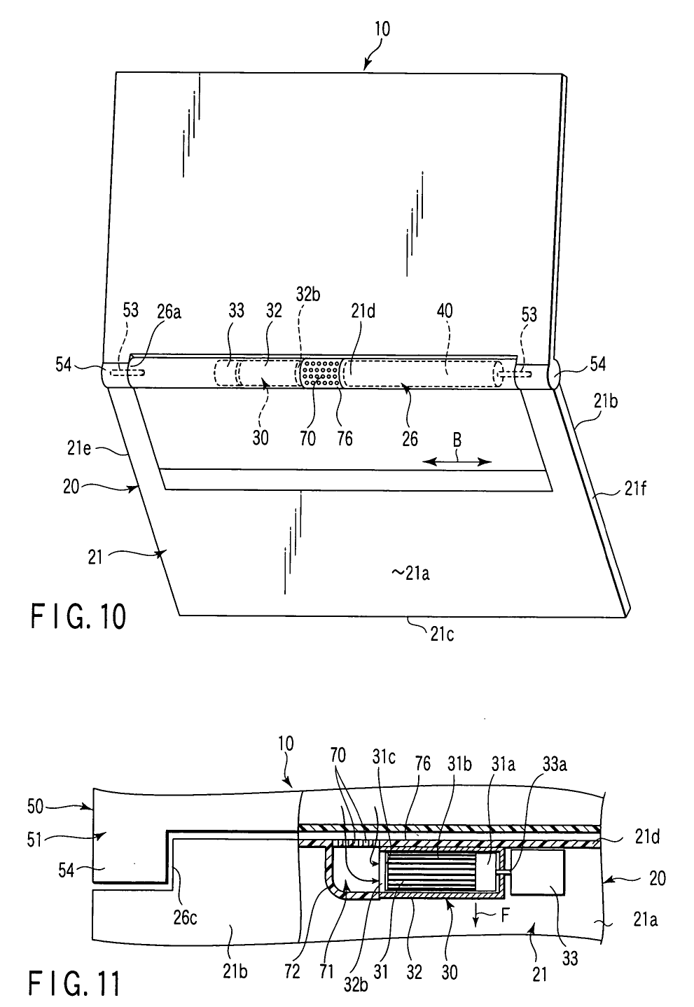

Next, a portable computer 10 will be described according to a third embodiment of the present invention with reference to FIGS. 10 and 11.

In the third embodiment, an arrangement of a fan unit 30 is different from that in the first embodiment. A connecting portion 54 is disposed in a portion of a second housing 51 in which a facing portion 55 has been disposed. It is to be noted that a constitution having a function similar to that of the first embodiment is denoted with the same reference numerals, and description thereof is omitted.

FIG. 10 is a perspective view of the portable computer 10 viewed from its rear according to the third embodiment, and FIG. 11 is a sectional view showing a state in which the vicinity of the fan unit 30 is viewed from above.

As shown in FIGS. 10 and 11, in the third embodiment, the fan unit 30 is disposed in, for example, a substantially central portion of a fan housing section 26 in a width direction B.

Suction ports 70 are formed in a portion of the rear wall 21d of a first housing 21. The suction ports 70 face an opened end 32b. The suction ports 70 open in a rear surface 76 of a rear wall 21d. The suction ports 70 communicate with the inside and the outside of the fan housing section 26. The rear wall 21d may have one suction port 70 only, not a plurality of the suction ports 70 as described above. As shown in FIG. 11, a guide portion 71 is disposed between the suction ports 70 and the opened end 32b of the fan unit 30.

The guide portion 71 is constituted by covering a space between the suction ports 70 and the opened end 32b of the fan unit 30 with, for example, a wall 72. The wall 72 may be formed integrally with, for example, the first housing 21. The guide portion 71 guides the air through the suction ports 70 into the fan unit 30.

Even in the portable computer 10 of the third embodiment, an effect similar to that of the first embodiment can be obtained. Furthermore, the fan unit 30 can effectively suck the air by means of the guide portion 71.

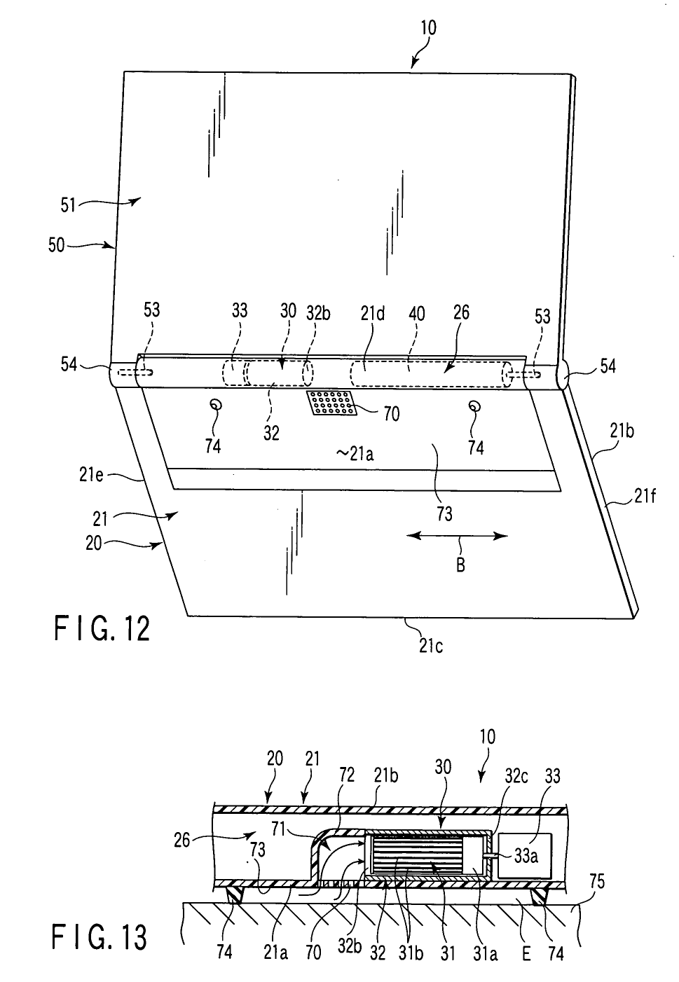

Next, there will be described a portable computer 10 according to a fourth embodiment of the present invention with reference to FIGS. 12 and 13. In the fourth embodiment, positions of suction ports 70 and a guide portion 71 are different from those of the suction ports 70 in the third embodiment. It is to be noted that a constitution having a function similar to that of the first or third embodiment is denoted with the same reference numerals, and description thereof is omitted.

FIG. 12 is a perspective view of a portable computer 10 viewed from its rear according to the fourth embodiment. FIG. 13 is a sectional view of the vicinity of a fan unit 30 along a vertical direction in a state in which the portable computer 10 is laid on a base 75.

As shown in FIGS. 12 and 13, in the fourth embodiment, the fan unit 30 is disposed in, for example, a substantially central portion of a fan housing section 26.

The suction ports 70 are formed in a portion of a bottom wall 21a of a first housing 21 which faces an opened end 32b of the fan unit 30. The suction ports 70 communicate with the inside and the outside of the fan housing section 26. The bottom wall 21a may have one suction port 70 only, not a plurality of suction ports 70 as described above.

The guide portion 71 is disposed between the suction ports 70 and the opened end 32b of the fan unit 30. The guide portion 71 is constituted by covering a space between the suction ports 70 and the opened end 32b with, for example, a wall 72. The wall 72 may be formed integrally with, for example, the first housing 21.

A pair of leg portions 74 are disposed on portions of a bottom surface 73 of the bottom wall 21a of the first housing 21, which are positioned under the fan housing section 26. The suction ports 70 are sandwiched between the leg portions 74.

As shown in FIG. 13, the respective leg portions 74 are disposed in such a manner that postures are stabled, when the portable computer 10 is laid on, for example, the base 75 or the like.

When the portable computer 10 is laid on the base 75, a space E between the suction ports 70 and the base 75 is defined by the pair of leg portions 74. Air is guided into the suction ports 70 through the space E. Therefore, even when the suction ports 70 are formed in the bottom surface 73, the fan unit 30 can sufficiently suck the air.

In the fourth embodiment, even when the fan unit 30 is disposed in the substantially central portion of the fan housing section 26 in the width direction, and the suction ports 70 are formed in the bottom wall 21a of the first housing 21, an effect similar to that of the first embodiment can be obtained. Furthermore, the fan unit 30 can effectively suck the air by means of the guide portion 71.

It is to be noted that in the present embodiment, the leg portions 74 are formed on the bottom wall 21a of the first housing 21, but the present invention is not limited to the present embodiment. The leg portions 74 may be disposed on, for example, a left wall 21e and a right wall 21f of the first housing 21, respectively. In brief, the leg portions 74 may be disposed in such a manner as to define the space E under the bottom surface 73.

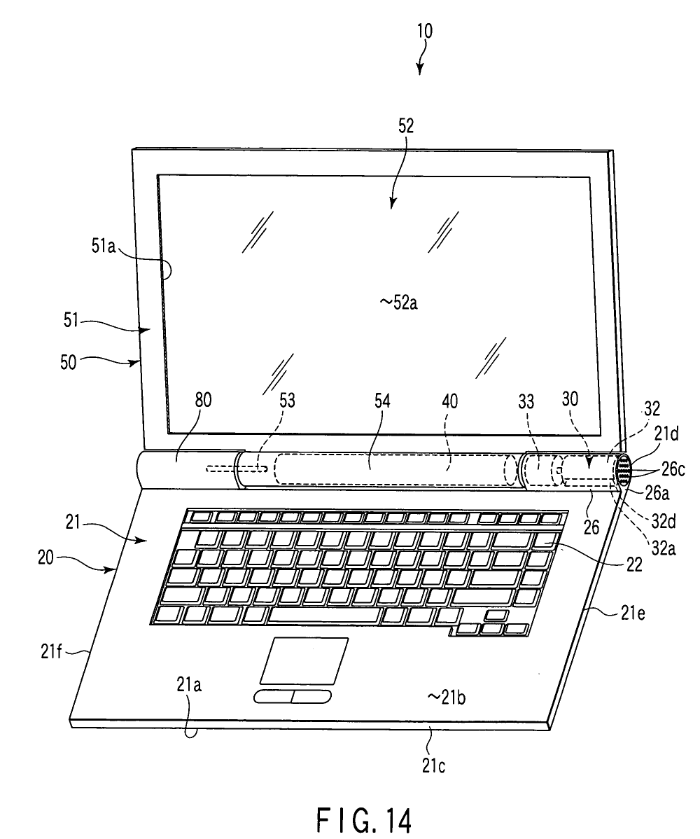

Next, there will be described a portable computer 10 according to a fifth embodiment of the present invention with reference to FIG. 14. In the fifth embodiment, an arrangement of a fan housing section 26 is different from that of the fan housing section 26 in the first embodiment. In a second housing 51, a position of a connecting portion 54 is different from that of the connecting portion 54 in the first embodiment. It is to be noted that in the present embodiment, any facing portion 55 is not formed in the second housing 51. A constitution having a function similar to that of the first embodiment is denoted with the same reference numerals, and description thereof is omitted.

FIG. 14 is a perspective view of the portable computer 10 viewed from its front according to the fifth embodiment. As shown in FIG. 14, in the fifth embodiment, the fan housing section 26 is formed in a left end of a rear end portion of a first housing 21. The fan housing section 26 has a predetermined length extending inwardly from the left end of the rear end portion of the first housing 21 in a width direction B.

In the present embodiment, a left end wall 26a of the fan housing section 26 is directed outwards. Therefore, suction ports 26c are formed in the left end wall 26a. A fan unit 30 sucks air through the suction ports 26c. It is to be noted that the left end wall 26a is a part of the left wall 21e. The left end wall 26a may have one suction port 26c only, not a plurality of suction ports as described above.

An attaching portion 80 is formed in a right end of the rear end portion of the first housing 21. The attaching portion 80 has a predetermined length extending inwardly from the right end of the rear end portion of the first housing 21 in the width direction B.

The second housing 51 is provided with the connecting portion 54 formed between the fan housing section 26 and the attaching portion 80. A shaft 53 is passed through the attaching portion 80 of the first housing 21 and the connecting portion 54 of the second housing 51 in the width direction B. Accordingly, the first housing 21 is rotatably connected to the second housing 51.

It is to be noted that in the fifth embodiment, a space from the suction ports 26c to an opened end 32b of the fan unit 30 has a substantially straight-line shape in the fan housing section 26. Furthermore, an interval between the suction ports 26c and the opened end 32b is comparatively short.

Therefore, in the fan housing section 26, the space from the suction ports 26c to the fan unit 30 sufficiently functions as a guide portion which guides outside air into the fan unit 30. That is, the fan housing section 26 also functions as a guide portion in the fifth embodiment.

An effect similar to that of the first embodiment can be obtained even in the portable computer 10 of the fifth embodiment. It is to be noted that in the fifth embodiment, a battery 40 is housed in, for example, the connecting portion 54 of the second housing 51.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general invention concept as defined by the appended claims and their equivalents.

What is claimed is:

1. An electronic device comprising:
a first housing having a first attaching portion and containing a heat generating member;
a second housing rotatably connected to the first attaching portion; and
a fan unit which is housed in the first attaching portion and which feeds air into the first housing, the fan unit having a plurality of vanes which extend in a width direction of the first and second housings and which are concentrically arranged, the fan unit sucking air from a rotation shaft direction of the plurality of vanes and discharging the air in a direction crossing the rotation shaft.

2. The electronic device according to claim 1, wherein the second housing has a second attaching portion that faces the first attaching portion, when the second housing is connected to the first housing,
the first attaching portion has an opening formed in a surface which faces the second attaching portion, and
the fan unit sucks outside air via the opening.

3. The electronic device according to claim 1, wherein the first housing has a suction port, and a guide portion which guides outside air into the fan unit through the suction port.

4. The electronic device according to claim 3, wherein the suction port is disposed in a rear wall of the first housing.

5. The electronic device according to claim 3, wherein the suction port is disposed in a bottom wall of the first housing.

6. The electronic device according to claim 3, wherein the suction port is disposed in a side wall of the first housing.

7. The electronic device according to claim 1, wherein the second housing has a second attaching portion which faces the first attaching portion, when the second housing is connected to the first housing and which is provided with suction port in the surface of the second attaching portion on a side opposite to the surface of the second attaching portion that faces a side surface of the first attaching portion.

8. The electronic device according to claim 7, further comprising:
a guide member which is disposed to range from the first attaching portion to the second attaching portion, the guide member guiding the air sucked from the suction port toward the fan unit.

9. The electronic device according to claim 8, Wherein the suction port is formed in the guide member.

10. The electronic device according to claim 9, wherein the guide member has a cylindrical shape whose one end has a bottom portion,
the bottom portion extends through the second attaching portion to face the outside, and
the suction port is formed in the bottom portion.

11. The electronic device according to claim 10, wherein the bottom portion is disposed on the same plane as that of the second attaching portion on a side opposite to the first attaching portion.
